(19) United States
(12) Patent Application Publication
(10) Pub. No.: US 2020/0147696 A1
(43) Pub. Date: May 14, 2020

(54) METHOD FOR CONNECTING COMPONENTS BY MEANS OF A METAL PASTE

(71) Applicant: Heraeus Deutschland GmbH & Co. KG, Hanau (DE)

(72) Inventors: Wolfgang Schmitt, Rodgau (DE); Michael Schäfer, Künzell (DE); Susanne K. Duch, Bruchköbel (DE); Jens Nachreiner, Schlüchtern (DE); Ly May Chew, Bruchköbel (DE)

(21) Appl. No.: 16/604,248

(22) PCT Filed: Apr. 20, 2018
(86) PCT No.: PCT/EP2018/060155

§ 371 Date: Oct. 10, 2019

(30) Foreign Application Priority Data
May 12, 2017 (DE) 17170737.5

(51) Int. Cl. B22F 7/06; B23K 35/02; H01L 23/00; B22F 1/00

(52) U.S. Cl. CPC B22F 7/064; B23K 35/025; H01L 24/83; B23K 2101/42; B22F 1/0074; B22F 2998/10; H01L 24/75

(57) ABSTRACT

The invention relates to a method for connecting components, comprising the following steps: (1) applying a metal paste containing an organic solvent to the contact surface of a first component; (2) optionally applying the metal paste to the contact surface of a second component to be connected to the first component; (3) producing a sandwich arrangement with the two components and a layer of the metal paste in-between; (4) drying the layer of metal paste between the components; and (5) pressureless sintering of the sandwich arrangement comprising the layer of dried metal paste, the drying and the pressureless sintering being performed by irradiation with IR radiation with a peak wavelength in the wavelength range of between 750 and 1500 nm. The components can be selected from the group consisting of substrates, active components and passive components. One or both of the components can be permeable to IR radiation. Step (4) and/or step (5) can be carried out in an atmosphere containing oxygen or an oxygen-free atmosphere. In both cases, at least one of the components can have an oxidation-sensitive contact surface.

The invention relates to a method for connecting components by means of a metal paste.

In the field of power and consumer electronics, the connecting of components, which have a high pressure and temperature sensitivity, represents a particular challenge. This is why such pressure- and temperature-sensitive components are often connected to one another by means of adhesion. The adhesion technique has the disadvantage, however, that contact points between the components, which have an only insufficient heat conductivity or electrical conductivity, respectively, are created thereby.

A known solution of this problem is to connect components to be connected in a pressureless manner by means of sintering. Pressureless sintering represents a very simple method for connecting components in a stable manner.

A metal paste containing an organic solvent is thereby usually applied to the contact surface to be connected, of one of the or of both of the components to be connected and, facing one another, the contact surfaces to be connected are brought into contact with one another by means of the layer of the metal paste located in-between by forming a sandwich arrangement. The two contact surfaces, which face one another, of the components thereby form a joint overlap surface. A drying step follows at increased temperature and subsequent a sintering step, which is performed in a pressureless manner (without pressing) at further increased temperature, in the course of which the fixed mechanical connection between the components is created. Drying and sintering is usually performed in convection ovens. Depending on the size of the connecting or contact surface, respectively, or overlap surface, respectively, of the components to be connected, for example in the range of between 1 and 25 mm², this drying process of the prior art requires a time period in the range of between 30 and 180 minutes at oven temperatures in the range of between 100 and 160° C. When selecting a drying period, which is too short, unwanted imperfections form frequently, such as, for example, shrinkage cavities, in the layer, which is to still be sintered. Such pores or imperfections cannot only mechanically weaken the later connection in the form of the layer, which is then sintered, but also with regard to its electric conductivity as well as heat conductivity.

The present invention lies in effecting the drying as well as the pressureless sintering not by means of convection, but by means of IR radiation (infrared radiation).

The method according to the invention is a method for connecting components, comprising the following steps:

(1) applying a metal paste containing an organic solvent to the contact surface of a first component,

(2) optionally applying the metal paste to the contact surface of a second component to be connected to the first component,

(3) producing a sandwich arrangement with the two components and a layer of the metal paste in-between,

(4) drying the layer of the metal paste between the two components, and

(5) pressureless sintering the sandwich arrangement comprising the layer of dried metal paste,

characterized in that the drying and the pressureless sintering is performed by irradiation with IR radiation (infrared radiation) with a peak wavelength in the wavelength range of between 750 and 1500 nm.

The method according to the invention comprises the steps (1) to (5). They are in particular successive steps, specifically directly successive steps without intermediate steps.

As part of the invention, the term component is to preferably comprise individual parts. These individual parts can preferably not be split into smaller parts.

The components each have one, optionally also a plurality of contact surfaces. The contact surfaces are generally metallic, for example in the form of a metallization layer. The metal of the components or of the contact surfaces can be pure metal or an alloy of the metal. Aluminum, copper, silver, gold, nickel, palladium, iron and platinum are examples for the metal.

The contact surface of the components used in the method according to the invention is the range of, for example, between 1 and 150 mm², in particular between >20 and 150 mm², specifically between 40 and 150 mm². It is advantageous that the method according to the invention can specifically also be carried out with components comprising a large contact surface with nonetheless reasonably short period of drying and pressureless sintering, without thereby having to accept a formation of imperfections of the above-mentioned type.

The first and the second component to be connected thereto can be of the same type, i.e. they can for example be substrates in both cases, or they are each active or passive components or an active and a passive component. It is also possible, however, that the one component is a substrate and the other component is an active or passive component, or vice versa. The substrates, the active and the passive components are in particular parts, which are used in electronics.

The following embodiments can thus be differentiated, for example:

| First Component: | Second Component: |
|---|---|
| substrate | substrate |
| active component | passive component |
| passive component | active component |
| active component | active component |
| passive component | passive component |
| substrate | active component |
| substrate | passive component |
| passive component | Substrate |
| active components | Substrate |

IMS substrates (insulated metal substrates), DCB substrates (direct copper bonded substrates), AMB substrates (active metal braze substrates), ceramic substrates, PCBs (printed circuit boards) and leadframes are examples for substrates.

Diodes, LEDs (light emitting diodes), dies (semiconductor chips), IGBTs (insulated-gate bipolar transistors), ICs (integrated circuits) and MOSFETs (metal-oxide-semiconductor field-effect transistors) are examples for active components.

Sensors, base plates, cooling elements, resistors, capacitors and coils are examples for passive components.

A metal paste containing an organic solvent is applied to the contact surface of a first component in step (1) of the method according to the invention.

The metal paste containing organic solvent is a common metal paste, which is known to the person of skill in the art as means for producing a sintering connection between components or the contact surfaces thereof, respectively, also referred to as metal sintering paste. Such metal pastes contain, for example, between 25 and 90% by weight of sinterable metal particles, in particular silver particles, silver alloy particles, copper particles and/or copper alloy particles; between 5 and 30% by weight of organic solvent; between 0 and 65% by weight of metal precursor compounds (metal precursors), in particular silver oxide, silver carbonate; between 0 and 5% by weight of sintering aids, for example peroxides, formiates; and between 0 and 5% by weight of other additives, for example saturated fatty acids and/or polymers, such as ethyl cellulose or polyimide.

Such metal pastes are disclosed in a variety of embodiments, for example in WO 2016/071005 A1, EP 3 009 211 A1, WO 2016/028221 A1, WO 2015/193014 A1, WO 2014/177645 A1, WO 2014/170050 A1, WO 2011/026624 A1, WO 2011/026623 A1, EP 2 572 814 A1, EP 2 425 920 A1, and EP 2 158 997 A2.

The application of the metal paste to the contact surface of the first component can be performed by means of conventional methods, for example by means of printing methods, such as screen printing, stencil printing or jetting. On the other hand, the application of the metal paste can also be performed by means of dispensing technology, by means of pin transfer or by means of dipping.

The method according to the invention comprises an optional step (2). If step (2) takes place, the metal paste as already mentioned above is also applied to the contact surface of the second component. The above-mentioned application methods are possible application methods.

A sandwich arrangement with the two components and the metal paste in-between the two components is produced in step (3). For this purpose, either the first component with its contact surface, which is provided with the metal paste, is attached to the contact surface of the second component, which is optionally also provided with the metal paste, or the second component is attached with its contact surface, which is optionally provided with the metal paste, to the contact surface of the first component, which is provided with the metal paste. As a result, a layer of the metal paste is in-between the components to be connected.

The wet film thickness of the layer of the metal paste is preferably in the range of between 20 and 200 μm. Wet film thickness is understood here as the distance between the contact surfaces, which face one another or which are located opposite one another, respectively, of the components prior to the drying. The wet film layer can be dependent, for example, on the selected method for applying the metal paste. In the case of metal paste applied by means of screen printing methods, the wet film thickness can be, for example, in the range of between 20 and 50 μm, in the case of stencil printing, for example in the range of between 50 and 200 μm, in the case of dispensing application for example in the range of between 20 and 100 μm, and in the case of application by means of jetting, for example in the range of between 20 and 70 μm.

In step (4) of the method according to the invention, the layer of the metal paste in-between the contact surfaces of the two components is dried. In response to the drying, organic solvent is removed from the metal paste. According to a preferred embodiment, the portion of organic solvent in the dried metal paste is, for example, between 0 and 5% by weight or between 0 and <1% by weight, based on the original portion of organic solvent in the metal paste, i.e. application-ready metal paste. In other words, for example between 95 and 100% by weight or between >99 and 100% by weight of the organic solvent or solvents originally contained in the metal paste are removed in response to the drying according to this preferred embodiment.

The drying is performed by irradiation with IR radiation with a peak wavelength in the wavelength range of between 750 and 1500 nm, preferably of between 750 and 1200 nm. If desired, a support can simultaneously take place by means of convection, but this is neither necessary nor preferred. In other words, it is not only possible but also preferred to effect the drying solely by means of the irradiation with IR radiation with a peak wavelength in the wavelength range of between 750 and 1500 nm, preferably of between 750 and 1200 nm.

Examples for radiation sources, which can be used for such IR radiation, comprise common NIR emitters (near-infrared emitters). Such NIR emitters can be obtained, for example, from Heraeus. The NIR emitters can be, for example, high-performance short wave emitters. The emitter or the individual NIR emitters can be operated with a power output of, for example, in the range of between 15 and 100 W/cm (Watt per centimeter emitter length), preferably in the range of between 20 and 50 W/cm. The emitter surface temperature (spiral-wound filament temperature) of the NIR emitters thereby lies, for example, in the range of between 1800 and 3000° C., preferably in the range of between 1850 and 2500° C. Suitable NIR emitters have, for example, an emission spectrum with a maximum in the range of between 750 and 1500 nm, preferably of between 750 and 1200 nm, in particular between 750 and 1500 nm or between 750 and 1200 nm.

The IR radiation can be performed statically or in a pass-through plant, whereby the sandwich arrangements to be irradiated with components and metal paste to be dried in-between, and/or the IR radiation source or sources are moved relative to one another.

One of the or both components are permeable for the IR radiation, i.e. partially or completely, and are sufficiently permeable in any case for the purposes of the method according to the invention. In other words, at least one of the components does not completely absorb the IR radiation. The IR irradiation is performed through the one or through both of the components, which are permeable for the IR radiation. The case, in which the IR irradiation is performed only through one or the one component, which is permeable for the IR radiation, is preferred. The IR irradiation is preferably performed from above through the component located on the top. Substrates, such as ceramic substrates, active components, such as diodes, LEDs, dies, IGBTs, ICs, MOSFETs, and passive components, such as sensors, ceramic cooling elements, resistors, capacitors and coils, are examples for the components, which are permeable for the IR radiation.

The distance between IR radiation source or—more precisely—between radiation discharge surface of the IR radiation source or sources and the layer of the metal paste to be sintered in a pressureless manner, lies, for example, in the range of between 1 and 50 cm, preferably between 5 and 20 cm.

The contact surfaces, which face one another, of the two components form a joint overlap surface with one another. The contact surface of the component comprising the smaller contact surface is thereby generally utilized completely, i.e. the size of the overlap surface generally corresponds to that of the complete contact surface of the component comprising the smaller contact surface.

Depending on the size of the joint overlap surface formed from the contact surfaces, which face one another, of the two components, for example in the range of between 1 and 150 mm², the drying process, which is in particular effected solely by the IR irradiation, requires a time period of, for example, in the range of only between 1 and 60 minutes and is thus significantly shorter than in the case of the above-mentioned oven drying according to the prior art. No quality disadvantages are created as compared to the oven drying. In the case of small overlap surfaces at the lower end of the mentioned range, short drying periods are sufficient, in the case of large overlap surfaces, the drying periods are at the upper end of the mentioned range.

The person of skill in the art can select the IR irradiation parameters and/or the drying period for step (4) in such a way that a sintering or pre-sintering of the drying or dried metal paste can be avoided.

The sandwich arrangement comprising the layer of the dried metal paste is sintered in a pressureless manner in step (5) of the method according to the invention.

As in the case of the drying according to step (4), the pressureless sintering is also performed by irradiation with said IR radiation. Steps (4) and (5) can thereby advantageously immediately follow one another, for example in that the IR irradiation is continued after completion of the drying according to step (4) without interruption for the purposes of step (5). Steps (4) and (5) can thus virtually melt together. It is also possible, however, to perform step (4) and step (5) with interruption in-between and interim cool-down.

The pressureless sintering is performed by irradiation with IR radiation with a peak wavelength in the wavelength range of between 750 and 1500 nm, preferably between 750 and 1200 nm. If desired, a support can simultaneously take place by means of convection, but this is neither necessary nor preferred. In other words, it is not only possible but also preferred to effect the pressureless sintering solely by means of the irradiation with IR radiation with a peak wavelength in the wavelength range of between 750 and 1500 nm, preferably of between 750 and 1200 nm, as in the case of the drying.

With regard to the radiation sources for the IR radiation and the operating states thereof, reference is made to that, which has been mentioned above in connection with drying step (4).

As in the case of drying step (4), the IR irradiation can be performed statically or in a pass-through plant, whereby the sandwich arrangements to be irradiated with components and the metal paste, which is to be sintered in a pressureless manner, in-between and/or the IR radiation source or sources are moved relative to one another.

As in the case of the drying step (4), the IR irradiation is performed through the one or through both components, which are permeable for the IR radiation. The case, in which the IR irradiation is performed only through one or the one component, which is permeable for the IR irradiation, is preferred. The IR irradiation is preferably performed from above through the component located on the top.

The distance between IR radiation sources or—more precisely—between radiation discharge surface of the IR radiation source or sources and the layer of the metal paste to be sintered in a pressureless manner, lies, for example, in the range of between 1 and 50 cm, preferably between 5 and 20 cm.

Depending on the size of the joint overlap surface formed from the contact surfaces, which face one another, of the two components, for example in the range of between 1 and 150 mm², the pressureless sintering effected by the IR irradiation requires a time period of, for example, in the range of only between 15 and 90 minutes. No quality disadvantages are created as compared to a pressureless sintering in the oven. In the case of small overlap surfaces at the lower end of the mentioned range, short drying periods are sufficient for the pressureless sintering, in the case of large overlap surfaces, the drying periods are at the upper end of the mentioned range.

Step (4) as well as step (5) can be performed in an atmosphere, which is not subject to any particular limitations. Drying and pressureless sintering can thus be performed in an atmosphere, which contains oxygen, for example air. Even in the case of components comprising inherently oxidation-sensitive contact surface, such as, for example, a copper or nickel contact surface, operation can be performed in oxygenic atmosphere, for example air, presumably as a result of the comparatively short drying period made possible as a result of the method according to the invention and likewise short period of the pressureless sintering.

It goes without saying that it is also possible, if desired, to perform the drying and pressureless sintering in oxygen-free atmosphere. As part of the invention, an oxygen-free atmosphere is to be understood to be an atmosphere, the oxygen content of which is not more than 100 ppm vol. (ppm by volume), preferably not more than 10 ppm vol. and even more preferably not more than 1 ppm vol.

In summary, it should be noted that the method according to the invention for connecting components has advantages as compared to the prior art, which operates with convection, such as a shortening of the drying period and of the period of the pressureless sintering without loss of quality, the expansion of the applicability of the pressureless sinter joining technique also to components comprising large contact surface and the non-necessity of an inertization even in the case of working with components comprising oxidation-sensitive contact surface, for example copper or nickel contact surface.

### EXAMPLES

### Reference Example 1, Production of a Metal Paste

85 parts by weight of silver particles (with 0.6% by weight of lauric acid/stearic acid in the weight ratio 25:75 of coated silver flakes), 7.4 parts by weight of α-terpineol, 7.4 parts by weight of iso-tridecanol and 0.2 parts by weight of ethyl cellulose were mixed to form a metal paste.

### Reference Example 2, Application of the Metal Paste from Example 1 and Forming a Sandwich Arrangement

The metal paste from example 1 was applied over the entire surface of a DCB substrate in a wet film layer of 75 μm and comprising a surface of 4 mm-4 mm by means of stencil printing. A silicon chip comprising a silver contact surface of 4 mm-4 mm was attached to the paste applied in this way by forming a sandwich arrangement comprising a joint overlap surface of DCB substrate and chip of 4 mm-4 mm.

### Reference Example 3a, Drying of the Sandwich Arrangement from Example 2 in an Oven

The sandwich arrangement created according to example 2 was dried under nitrogen atmosphere at 150° C. oven temperature, except for a residual solvent content of <0.5% by weight, based on organic solvent originally contained in the metal paste (gravimetrically determined). The drying process required 60 minutes.

### Reference Example 3b, Drying the Sandwich Arrangement from Example 2 Under IR Irradiation

The sandwich arrangement created according to example 2 was irradiated with an NIR emitter of a length of 30 cm, a power output of 30 W/cm, a filament temperature of 2009° C., and with a peak wavelength of 1100 nm from above the silicon chip in air from a distance of 10 cm, and was thus freed from the organic solvent except for a residual solvent content of <0.5% by weight, based on organic solvent originally contained in the metal paste (gravimetrically determined). The drying process effected solely by means of the IR irradiation required 10 minutes.

### Comparative Example 4a, Pressureless Sintering of the Sandwich Arrangement Dried According to Example 3a in an Oven

The sandwich arrangement created according to example 3a was sintered in a convection oven under nitrogen atmosphere in a pressureless manner for 60 minutes at 230° C. oven temperature. After the cool-down, the adhesion was determined via the shear strength. The silicon chips were thereby sheared by means of a shearing chisel at a speed of 0.3 mm/s at 260° C. The force was recorded by means of a measuring box (device DAGE 2000 by DAGE, Germany). Shear strengths of above 20 N/mm² represent satisfactory results. Measured shear strength: 23 N/mm².

### Comparative Example 4b, Pressureless Sintering of the Sandwich Arrangement Dried According to Example 3b in an Oven

The sandwich arrangement dried according to example 3b was sintered in a convection oven under nitrogen atmosphere in a pressureless manner for 60 minutes at 230° C. oven temperature. The adhesion was then determined via the shear strength, as in example 4a. Measured shear strength: 24 N/mm².

### Example 4c According to the Invention, Pressureless Sintering of the Sandwich Arrangement Dried According to Example 3b Under IR Irradiation

The sandwich arrangement dried according to example 3b was irradiated with an NIR emitter of a length of 30 cm, a power output of 30 W/cm, a filament temperature of 2009° C., and with a peak wavelength of 1100 nm for 20 minutes from above the silicon chip from a distance of 10 cm, and was thus sintered in a pressureless manner, in that the IR irradiation process from example 3b was continued without interruption. The adhesion was then determined via the shear strength, as in example 4a. Measured shear strength: 21 N/mm².

### Reference Example 5, Application of the Metal Paste from Example 1 and Formation of a Sandwich Arrangement

The metal paste from example 1 was applied over the entire surface of a DCB substrate in a wet film layer of 75 μm and comprising a surface of 5 mm-8 mm by means of stencil printing. A silicon chip comprising a silver contact surface of 5 mm-8 mm was attached to the paste applied in this way by forming a sandwich arrangement comprising a joint overlap surface of DCB substrate and chip of 5 mm-8 mm.

### Reference Example 6a, Drying of the Sandwich Arrangement from Example 5 in an Oven

The sandwich arrangement created according to example 5 was dried under nitrogen atmosphere at 150° C. oven temperature, except for a residual solvent content of <0.5% by weight, based on organic solvent originally contained in the metal paste (gravimetrically determined). The drying process required 90 minutes.

### Reference Example 6b, Drying of the Sandwich Arrangement from Example 5 Under IR Irradiation

The sandwich arrangement created according to example 5 was irradiated with an NIR emitter of a length of 30 cm, a power output of 30 W/cm, a filament temperature of 2009° C., and with a peak wavelength of 1100 nm from above the silicon chip in air from a distance of 10 cm, and was thus freed from the organic solvent except for a residual solvent content of <0.5% by weight, based on organic solvent originally contained in the metal paste (gravimetrically determined). The drying process effected solely by the IR irradiation required 20 minutes.

### Comparative Example 7a, Pressureless Sintering of the Sandwich Arrangement Dried According to Example 6a in an Oven

The sandwich arrangement created according to example 6a was sintered in a convection oven under nitrogen atmosphere in a pressureless manner for 60 minutes at 230° C. oven temperature. After the cool-down, the adhesion was determined via the shear strength. The silicon chips were thereby sheared by means of a shearing chisel at a speed of 0.3 mm/s at 260° C. The force was recorded by means of a measuring box (device DAGE 2000 by DAGE, Germany). Measured shear strength: 22 N/mm².

### Comparative Example 7b, Pressureless Sintering of the Sandwich Arrangement Dried According to Example 6b in an Oven

The sandwich arrangement created according to example 6b was sintered in a convection oven under nitrogen atmosphere in a pressureless manner for 60 minutes at 230° C. oven temperature. The adhesion was then determined via the shear strength, as in example 7a. Measured shear strength: 22 N/mm².

### Example 7c According to the Invention, Pressureless Sintering of the Sandwich Arrangement Dried According to Example 6b Under IR Irradiation

The sandwich arrangement dried according to example 6b was irradiated with an NIR emitter of a length of 30 cm, a power output of 30 W/cm, a filament temperature of 2009° C., and with a peak wavelength of 1100 nm for 20 minutes from above the silicon chip from a distance of 10 cm, and was thus sintered in a pressureless manner, in that the IR irradiation process from example 6b was continued without interruption. The adhesion was then determined via the shear strength, as in example 7a. Measured shear strength: 23 N/mm².

1. A method for connecting components, comprising the following steps:
(1) applying a metal paste containing an organic solvent to the contact surface of a first component,
(2) optionally applying the metal paste to the contact surface of a second component to be connected to the first component,
(3) producing a sandwich arrangement with the first and second components and a layer of the metal paste in-between,
(4) drying the layer of the metal paste between the first and second components, and
(5) pressureless sintering the sandwich arrangement comprising the layer of dried metal paste,
wherein the drying and the pressureless sintering is performed by irradiation with infrared (IR) radiation with a peak wavelength in the wavelength range of between 750 and 1500 nm.

2. The method of claim 1, wherein the contact surface of the first and second components lies in the range of between 1 and 150 mm².

3. The method of claim 1, wherein the first and second components are selected from the group consisting of substrates, active components and passive components.

4. The method of claim 1, wherein the metal paste applied in step (1) and optionally in step (2) contains between 25 and 90% by weight of sinterable metal particles, between 5 and 30% by weight of the organic solvent, between 0 and 65% by weight of metal precursor compounds, between 0 and 5% by weight of sintering aids, and between 0 and 5% by weight of other additives.

5. The method claim 1, wherein between 95 and 100% by weight of the organic solvent originally contained in the metal paste are removed during step (4).

6. The method claim 1, wherein the peak wavelength lies in the wavelength range of between 750 and 1200 nm.

7. The method claim 1, wherein the drying and the pressureless sintering are in each case effected solely by means of the irradiation with IR radiation.

8. The method claim 1, wherein one or a plurality of near-infrared (NIR) emitters, which are operated with a power output in the range of between 15 and 100 W/cm, are used as radiation sources for the IR radiation.

9. The method of claim 8, wherein the emitter surface temperature of the one or plurality of NIR emitters lies in the range of between 1800 and 3000° C.

10. The method of claim 1, wherein one or both of the first and second components are permeable for the IR radiation.

11. The method according to claim 10, wherein the IR irradiation is performed from above through the component, which is located on the top and which is permeable for the IR radiation.

12. The method of claim 1, wherein the distance between a radiation discharge surface of an IR radiation source or sources and the layer of the metal paste lies in the range of between 1 and 50 cm.

13. The method of claim 1, wherein step (4) and step (5) are performed in an oxygenic or in an oxygen-free atmosphere, wherein, in both cases, one or both of the first and second components have an oxidation-sensitive contact surface.

14. The method of claim 1, wherein steps (4) and (5) immediately follow one another.
